(19) United States
(12) Patent Application Publication
(10) Pub. No.: US 2014/0151757 A1
(43) Pub. Date: Jun. 5, 2014

(54) SUBSTRATE-TEMPLATED EPITAXIAL SOURCE/DRAIN CONTACT STRUCTURES

(71) Applicant: INTERNATIONAL BUSINESS MACHINES CORPORATION, Armonk, NY (US)

(72) Inventors: Anirban Basu, Elmsford, NY (US); Josephine B. Chang, Mahopac, NY (US); Michael A. Guillorn, Yorktown Heights, NY (US); Amlan Majumdar, White Plains, NY (US)

(73) Assignee: INTERNATIONAL BUSINESS MACHINES CORPORATION, Armonk, NY (US)

(21) Appl. No.: 13/692,162

(22) Filed: Dec. 3, 2012

(51) Int. Cl. H01L 29/78; H01L 21/76

(52) U.S. Cl. CPC H01L 29/78; H01L 21/76; B82Y 40/00
USPC 257/288; 438/400; 977/762

(57) ABSTRACT

Single crystalline semiconductor fins are formed on a single crystalline buried insulator layer. After formation of a gate electrode straddling the single crystalline semiconductor fins, selective epitaxy can be performed with a semiconductor material that grows on the single crystalline buried insulator layer to form a contiguous semiconductor material portion. The thickness of the deposited semiconductor material in the contiguous semiconductor material portion can be selected such that sidewalls of the deposited semiconductor material portions do not merge, but are conductively connected to one another via horizontal portions of the deposited semiconductor material that grow directly on a horizontal surface of the single crystalline buried insulator layer. Simultaneous reduction in the contact resistance and parasitic capacitance for a fin field effect transistor can be provided through the contiguous semiconductor material portion and cylindrical contact via structures.

### BACKGROUND

The present disclosure relates to semiconductor structures, and particularly to fin field effect transistors including substrate-templated epitaxial source/drain contact structures and a method of manufacturing the same.

In semiconductor devices including “finned” source/drain regions, there is a tradeoff between low external resistance and low parasitic capacitance. Non-merged source/drain regions provide a larger contact area and lower contact resistance relative to merged source/drain regions, but require a bar contact which increases parasitic capacitance of a gate electrode. Merged source/drain regions allow the use of cylindrical via structures and improve the routability in the layout and reduce the gate-to-contact parasitic resistance, but increase the contact resistance.

### BRIEF SUMMARY

Single crystalline semiconductor fins are formed on a single crystalline buried insulator layer. After formation of a gate electrode straddling the single crystalline semiconductor fins, selective epitaxy can be performed with a semiconductor material that grows on the single crystalline buried insulator layer to form a contiguous semiconductor material portion. The thickness of the deposited semiconductor material in the contiguous semiconductor material portion can be selected such that sidewalls of the deposited semiconductor material portions do not merge, but are conductively connected to one another via horizontal portions of the deposited semiconductor material that grow directly on a horizontal surface of the single crystalline buried insulator layer. Simultaneous reduction in the contact resistance and parasitic capacitance for a fin field effect transistor can be provided through the contiguous semiconductor material portion and cylindrical contact via structures.

According to an aspect of the present disclosure, a method of forming a semiconductor structure is provided. At least one semiconductor material portion is formed on a single crystalline dielectric layer. A gate electrode straddling the at least one semiconductor material portion is formed. A contiguous single crystalline semiconductor portion is formed directly on an end subportion of each of the at least one semiconductor material portion by depositing a semiconductor material in epitaxial alignment with the single crystalline dielectric layer.

According to another aspect of the present disclosure, a semiconductor structure includes a substrate containing a single crystalline dielectric layer. At least one semiconductor material portion is located on the single crystalline dielectric layer. A gate electrode straddles the at least one semiconductor material portion. A contiguous single crystalline semiconductor portion contacts an end subportion of each of the at least one semiconductor material portion, and has a single crystalline structure in epitaxial alignment with the single crystalline dielectric layer.

### BRIEF DESCRIPTION OF SEVERAL VIEWS OF THE DRAWINGS

FIG. 1A is a top-down view of a first exemplary semiconductor structure after formation of a shallow trench isolation structure according to a first embodiment of the present disclosure.

FIG. 1B is a vertical cross-sectional view of the first exemplary semiconductor structure along the vertical plane B-B′ of FIG. 1A.

FIG. 1C is a vertical cross-sectional view of the first exemplary semiconductor structure along the vertical plane C-C′ of FIG. 1A.

FIG. 2A is a top-down view of the first exemplary semiconductor structure after formation of semiconductor fins according to the first embodiment of the present disclosure.

FIG. 2B is a vertical cross-sectional view of the first exemplary semiconductor structure along the vertical plane B-B′ of FIG. 2A.

FIG. 2C is a vertical cross-sectional view of the first exemplary semiconductor structure along the vertical plane C-C′ of FIG. 2A.

FIG. 3A is a top-down view of the selected region of the first exemplary semiconductor structure after removal of a patterned photoresist layer according to the first embodiment of the present disclosure.

FIG. 3B is a vertical cross-sectional view of the first exemplary semiconductor structure along the vertical plane B-B′ of FIG. 3A.

FIG. 3C is a vertical cross-sectional view of the first exemplary semiconductor structure along the vertical plane C-C′ of FIG. 3A.

FIG. 4A is a top-down view of the first exemplary semiconductor structure after formation of gate stacks and gate spacers according to the first embodiment of the present disclosure.

FIG. 4B is a vertical cross-sectional view of the first exemplary semiconductor structure along the vertical plane B-B′ of FIG. 4A.

FIG. 4C is a vertical cross-sectional view of the first exemplary semiconductor structure along the vertical plane C-C′ of FIG. 4A.

FIG. 5A is a top-down view of the first exemplary semiconductor structure after formation of epitaxially aligned contiguous semiconductor material portions that electrically short multiple semiconductor fins according to the first embodiment of the present disclosure.

FIG. 5B is a vertical cross-sectional view of the first exemplary semiconductor structure along the vertical plane B-B′ of FIG. 5A.

FIG. 5C is a vertical cross-sectional view of the first exemplary semiconductor structure along the vertical plane C-C′ of FIG. 5A.

FIG. 6A is a top-down view of the first exemplary semiconductor structure after formation of source and drain regions according to the first embodiment of the present disclosure.

FIG. 6B is a vertical cross-sectional view of the first exemplary semiconductor structure along the vertical plane B-B′ of FIG. 6A.

FIG. 6C is a vertical cross-sectional view of the first exemplary semiconductor structure along the vertical plane C-C′ of FIG. 6A.

FIG. 7A is a top-down view of a second exemplary semiconductor structure after removal of physically exposed portions of semiconductor fins according to a second embodiment of the present disclosure.

FIG. 7B is a vertical cross-sectional view of the second exemplary semiconductor structure along the vertical plane B-B′ of FIG. 7A.

FIG. 7C is a vertical cross-sectional view of the second exemplary semiconductor structure along the vertical plane C-C′ of FIG. 7A.

FIG. 8A is a top-down view of the second exemplary semiconductor structure after formation of epitaxially aligned contiguous semiconductor material portions that electrically short multiple semiconductor fins according to the second embodiment of the present disclosure.

FIG. 8B is a vertical cross-sectional view of the second exemplary semiconductor structure along the vertical plane B-B′ of FIG. 8A.

FIG. 8C is a vertical cross-sectional view of the second exemplary semiconductor structure along the vertical plane C-C′ of FIG. 8A.

FIG. 9A is a top-down view of a third exemplary semiconductor structure after formation of a semiconductor-fin containing structure according to a third embodiment of the present disclosure.

FIG. 9B is a vertical cross-sectional view of the third exemplary semiconductor structure along the vertical plane B-B′ of FIG. 9A.

FIG. 9C is a vertical cross-sectional view of the third exemplary semiconductor structure along the vertical plane C-C′ of FIG. 9A.

FIG. 10A is a top-down view of the third exemplary semiconductor structure after removal of a patterned photoresist layer according to the third embodiment of the present disclosure.

FIG. 10B is a vertical cross-sectional view of the third exemplary semiconductor structure along the vertical plane B-B′ of FIG. 10A.

FIG. 10C is a vertical cross-sectional view of the third exemplary semiconductor structure along the vertical plane C-C′ of FIG. 10A.

FIG. 11A is a top-down view of a third exemplary semiconductor structure after formation of suspended semiconductor fins according to a third embodiment of the present disclosure.

FIG. 11B is a vertical cross-sectional view of the third exemplary semiconductor structure along the vertical plane B-B′ of FIG. 11A.

FIG. 11C is a vertical cross-sectional view of the third exemplary semiconductor structure along the vertical plane C-C′ of FIG. 11A.

FIG. 12A is a top-down view of the third exemplary semiconductor structure after formation of semiconductor nanowires according to the third embodiment of the present disclosure.

FIG. 12B is a vertical cross-sectional view of the third exemplary semiconductor structure along the vertical plane B-B′ of FIG. 12A.

FIG. 12C is a vertical cross-sectional view of the third exemplary semiconductor structure along the vertical plane C-C′ of FIG. 12A.

FIG. 13A is a top-down view of the third exemplary semiconductor structure after formation of a gate dielectric layer according to the third embodiment of the present disclosure.

FIG. 13B is a vertical cross-sectional view of the third exemplary semiconductor structure along the vertical plane B-B′ of FIG. 13A.

FIG. 13C is a vertical cross-sectional view of the third exemplary semiconductor structure along the vertical plane C-C′ of FIG. 13A.

FIG. 14A is a top-down view of the third exemplary semiconductor structure after formation of gate electrodes according to a third embodiment of the present disclosure.

FIG. 14B is a vertical cross-sectional view of the third exemplary semiconductor structure along the vertical plane B-B′ of FIG. 14A.

FIG. 14C is a vertical cross-sectional view of the third exemplary semiconductor structure along the vertical plane C-C′ of FIG. 14A.

FIG. 15A is a top-down view of the third exemplary semiconductor structure after formation of gate spacers according to the third embodiment of the present disclosure.

FIG. 15B is a vertical cross-sectional view of the third exemplary semiconductor structure along the vertical plane B-B′ of FIG. 15A.

FIG. 15C is a vertical cross-sectional view of the third exemplary semiconductor structure along the vertical plane C-C′ of FIG. 15A.

FIG. 16A is a top-down view of the third exemplary semiconductor structure after removal of physically exposed portions of a gate dielectric layer according to the third embodiment of the present disclosure.

FIG. 16B is a vertical cross-sectional view of the third exemplary semiconductor structure along the vertical plane B-B′ of FIG. 16A.

FIG. 16C is a vertical cross-sectional view of the third exemplary semiconductor structure along the vertical plane C-C′ of FIG. 16A.

FIG. 17A is a top-down view of the third exemplary semiconductor structure after formation of epitaxially aligned contiguous semiconductor material portions that electrically short multiple semiconductor fins according to the third embodiment of the present disclosure.

FIG. 17B is a vertical cross-sectional view of the third exemplary semiconductor structure along the vertical plane B-B′ of FIG. 17A.

FIG. 17C is a vertical cross-sectional view of the third exemplary semiconductor structure along the vertical plane C-C′ of FIG. 17A.

FIG. 18A is a top-down view of the third exemplary semiconductor structure after formation of source/drain regions according to the third embodiment of the present disclosure.

FIG. 18B is a vertical cross-sectional view of the third exemplary semiconductor structure along the vertical plane B-B′ of FIG. 18A.

FIG. 18C is a vertical cross-sectional view of the third exemplary semiconductor structure along the vertical plane C-C′ of FIG. 18A.

FIG. 19A is a top-down view of a fourth exemplary semiconductor structure after removal of physically exposed portions of the semiconductor fins according to a fourth embodiment of the present disclosure.

FIG. 19B is a vertical cross-sectional view of the fourth exemplary semiconductor structure along the vertical plane B-B′ of FIG. 19A.

FIG. 19C is a vertical cross-sectional view of the fourth exemplary semiconductor structure along the vertical plane C-C′ of FIG. 19A.

FIG. 20A is a top-down view of the fourth exemplary semiconductor structure after formation of epitaxially aligned contiguous semiconductor material portions that electrically short multiple semiconductor fins according to a fourth embodiment of the present disclosure.

FIG. 20B is a vertical cross-sectional view of the fourth exemplary semiconductor structure along the vertical plane B-B′ of FIG. 20A.

FIG. 20C is a vertical cross-sectional view of the fourth exemplary semiconductor structure along the vertical plane C-C′ of FIG. 20A.

### DETAILED DESCRIPTION

As stated above, the present disclosure relates to fin field effect transistors including substrate-templated epitaxial source/drain contact structures and a method of manufacturing the same. Aspects of the present disclosure are now described in detail with accompanying figures. It is noted that like reference numerals refer to like elements across different embodiments. The drawings are not necessarily drawn to scale.

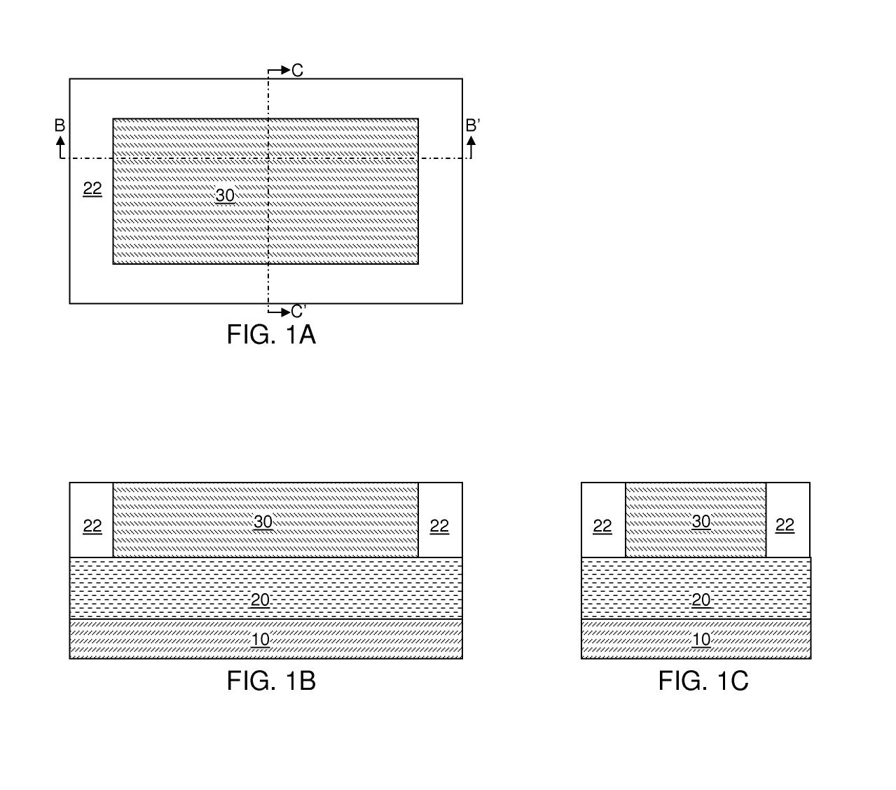

Referring to FIGS. 1A-1C, a first exemplary semiconductor structure according to a first embodiment of the present disclosure includes a substrate that contains a single crystalline dielectric layer 20, and a top semiconductor portion 30 formed by patterning a top semiconductor layer to embed a shallow trench isolation structure 22 therein.

In one embodiment, the single crystalline dielectric layer 20 can be provided on a handle substrate 10. A top semiconductor layer including a dielectric material can be provided over the single crystalline dielectric layer 20. In one embodiment, the top semiconductor can have a single crystalline structure that is in epitaxial alignment with the single crystalline structure of the single crystalline dielectric layer 20. Additionally, the handle substrate 10 can be single crystalline, and the single crystalline dielectric layer 20 can be in epitaxial alignment with the single crystalline structure of the handle substrate 10.

In one embodiment, the single crystalline dielectric layer 20 can be formed by epitaxial deposition of a crystalline dielectric material on the handle substrate 10. In this case, the handle substrate 10 includes a single crystalline semiconductor material, a single crystalline dielectric material, or a single crystalline conductive material. As used herein, a semiconductor material refers to a material having electrical conductivity in a range from 1.0×10⁻⁵ Ohm-cm to 1.0×10⁵ Ohm-cm at 298.15 K and 1 atm. As used herein, a dielectric material refers to a material having electrical conductivity less than 1.0×10⁻⁵ Ohm-cm at 298.15 K and 1 atm. As used herein, a conductive material refers to a material having electrical conductivity greater than 1.0×10⁵ Ohm-cm at 298.15 K and 1 atm.

In one embodiment, the handle substrate 10 can be an indium phosphide (InP) single crystalline substrate, the single crystalline dielectric layer 20 can be an intrinsic indium aluminum arsenide (InₓAl₁₋ₓAs), and the top semiconductor layer can be a single crystalline III-V compound semiconductor material layer. The value of x can be a variable with a vertical distance from the interface between the handle substrate 10 and the single crystalline dielectric layer 20, or can be a constant. The value of x can be in a range from 0.2 to 0.8, although lesser and greater values can also be employed provided that single crystalline structure of the single crystalline dielectric layer 20 can be maintained throughout the epitaxial deposition process that forms the single crystalline dielectric layer 20. For example, the value of x can be selected to be about 0.52 at the interface with the handle substrate 10 and can be gradually varied in order to provide the same lattice constant with the III-V compound semiconductor material to be subsequently deposited to form the top semiconductor layer. In general, the single crystalline dielectric layer 20 can include a compound of at least one Group III element and at least one Group V element.

In one embodiment, the top semiconductor layer can include intrinsic indium gallium arsenide (In_{y}Ga_{1-y}As), in which the value of y can be in a range from 0.2 to 0.8, although lesser and greater values of y can also be employed. In one embodiment, the value of y can be greater than 0.53.

The thickness of the handle substrate 10 can be from 30 micron to 2 mm, although lesser and greater thicknesses can also be employed. The thickness of the single crystalline dielectric layer 20 can be from 100 nm to 100 microns, although lesser and greater thicknesses can also be employed. The thickness of the top semiconductor layer can be from 30 nm to 1,000 nm, although lesser and greater thicknesses can also be employed.

A shallow trench is formed through the top semiconductor layer in a pattern that laterally surrounds a portion of the top semiconductor layer. The shallow trench isolation structure 22 is formed by filling the shallow trench with a dielectric material such as silicon oxide, silicon nitride, silicon oxynitride, and subsequently removing portions of the dielectric material above the top surface of the top semiconductor layer. The dielectric material can be deposited, for example, by chemical vapor deposition (CVD). The removal of the dielectric material above the top surface of the top semiconductor layer can be performed, for example, by chemical mechanical planarization (CMP). The remaining portion of the top semiconductor layer that is laterally surrounded by the shallow trench isolation structure 22 constitutes a top semiconductor portion 30, which can have a rectangular shape as seen from above.

The top semiconductor portion 30 may be intrinsic or may be doped with dopants. If the top semiconductor portion 30 is doped, the type of doping of the top semiconductor portion 30 is herein referred to as a first conductivity type.

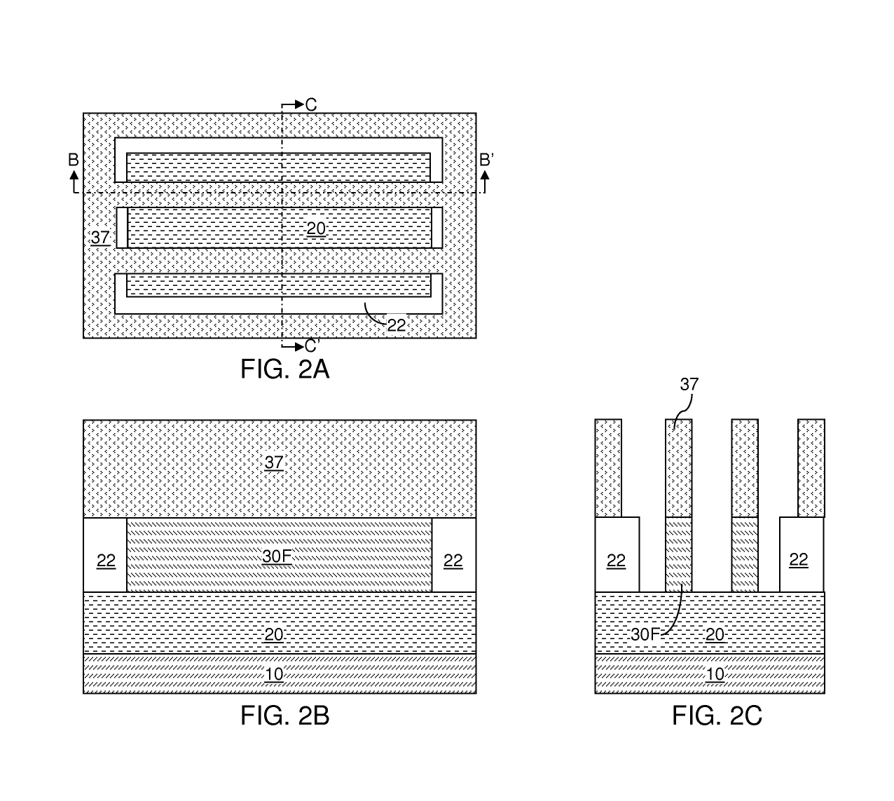

Referring to FIGS. 2A-2C, a photoresist layer 37 is applied over the top semiconductor portion 30 and the shallow trench isolation structure 22, and is lithographically exposed to form a pattern of fins over the top semiconductor portion 30.

Physically exposed portions of the semiconductor portion are etched by an anisotropic etch employing the photoresist layer 37 as an etch mask. In one embodiment, the anisotropic etch can be selective to the dielectric material of the shallow trench isolation structure 22. The remaining portions of the top semiconductor portion 30 can constitute semiconductor fins 30F. Each semiconductor fin 30F can have a horizontal rectangular cross-sectional shape having a pair of lengthwise edges that are longer than a pair of widthwise edges. In one embodiment, the semiconductor fins 30F can have a same rectangular horizontal cross-sectional shape. The width of each semiconductor fin 30F, which is the lateral distance between a pair of widthwise edges of a horizontal rectangular cross-sectional shape of a semiconductor fin 30F, can be from 20 nm to 100 nm, although lesser and greater widths can also be employed. The spacing between a neighboring pair of semiconductor fins 30F can be from 20 nm to 300 nm, although lesser and greater spacings can also be employed. Each semiconductor fin 30F is a semiconductor material portion located on the single crystalline dielectric layer 20. Each semiconductor fin 30F can be epitaxially aligned to the single crystal structure of the single crystalline dielectric layer 20.

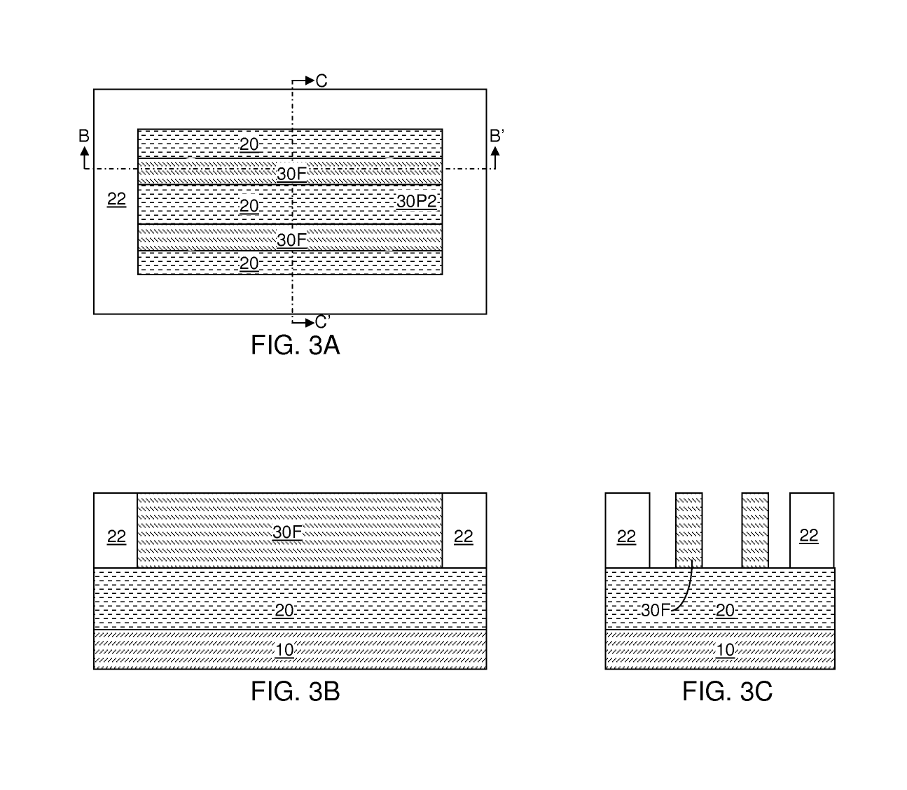

Referring to FIGS. 3A-3F, the photoresist layer 37 can be removed selective to the semiconductor fins 30F and the shallow trench isolation structure 22. In one embodiment, the semiconductor fins 30F can be a plurality of semiconductor fins 30F having parallel vertical sidewalls that extend along a horizontal lengthwise direction, i.e., the direction of the lengthwise edges of the horizontal rectangular cross-sectional shapes of the semiconductor fins 30F. Each of the plurality of semiconductor fins 30F can be single crystalline, and can be in epitaxial alignment with the single crystalline dielectric layer 20. In one embodiment, the shallow trench isolation structure 20 can contact vertical surfaces of each of the plurality of semiconductor fins 30F, which are semiconductor material portions. In one embodiment, each of the plurality of semiconductor fins 30F can extend along the horizontal lengthwise direction, and can have a substantially rectangular vertical cross-sectional shape within vertical planes perpendicular to the horizontal lengthwise direction. The height of the substantially rectangular vertical cross-sectional shape is the height of a semiconductor fin 30F, and the width of the substantially rectangular vertical cross-sectional shape is the width of the semiconductor fin 30F.

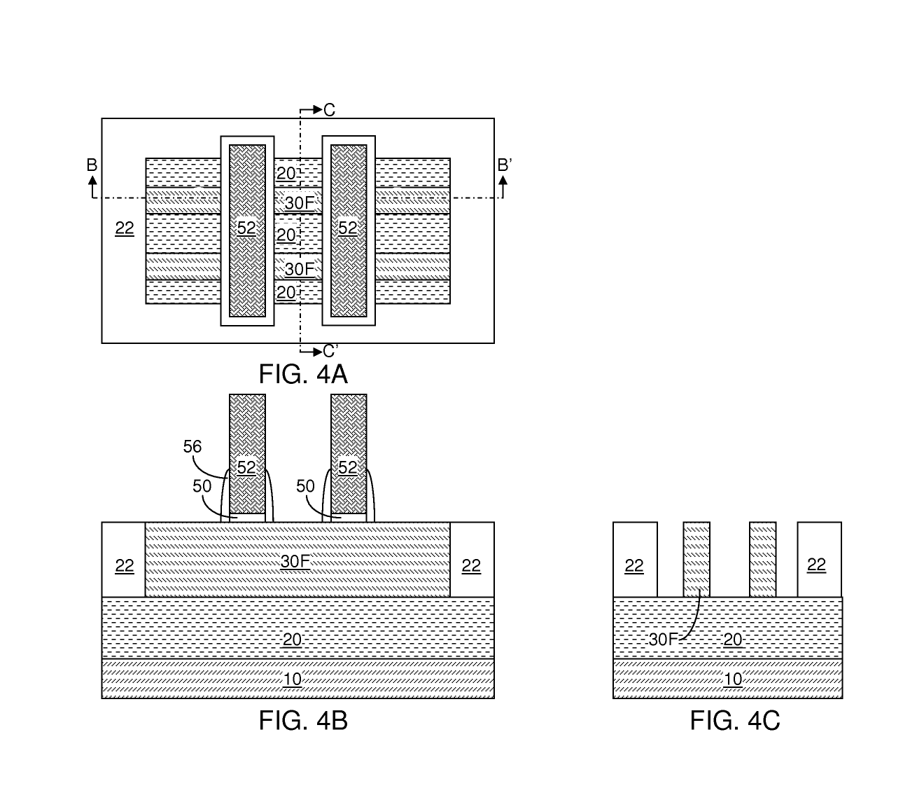

Referring to FIGS. 4A-4C, at least one gate stack can be formed over the plurality of semiconductor fins 30F. Each of the at least one gate stack includes a gate dielectric 50 and a gate electrode 52 that straddle a portion of each semiconductor fin 30F. Each gate dielectric 50 can include a high dielectric constant (high-k) dielectric material having a dielectric constant greater than 7.9 and/or a conventional gate dielectric material such as silicon oxide, silicon nitride, and/or silicon oxynitride. Each gate electrode 52 includes at least one conductive material, which can be a metallic material and/or a doped semiconductor material. Each gate stack (50, 52) can be formed, for example, by depositing a stack of a contiguous dielectric layer, gate metal layer, gate conductor layer, and gate hard mask layer, applying and patterning a photoresist layer above the gate stack layers, transferring the pattern in the photoresist layer through the gate conductor layer by an anisotropic etch employing the contiguous dielectric layer as an etch stop layer, and removing physically exposed portions of the contiguous dielectric layer selective to the semiconductor fins 30F by a wet etch or a dry etch.

A gate spacer 56 can be formed around each gate stack (50, 52), for example, by depositing a dielectric material layer and anisotropically etching the dielectric material layer. Each remaining vertical portions of the dielectric material layer constitutes a gate spacer 56. Each gate spacer 56 laterally surrounds a gate stack (50, 52) that includes a gate dielectric 50 and a gate electrode 52.

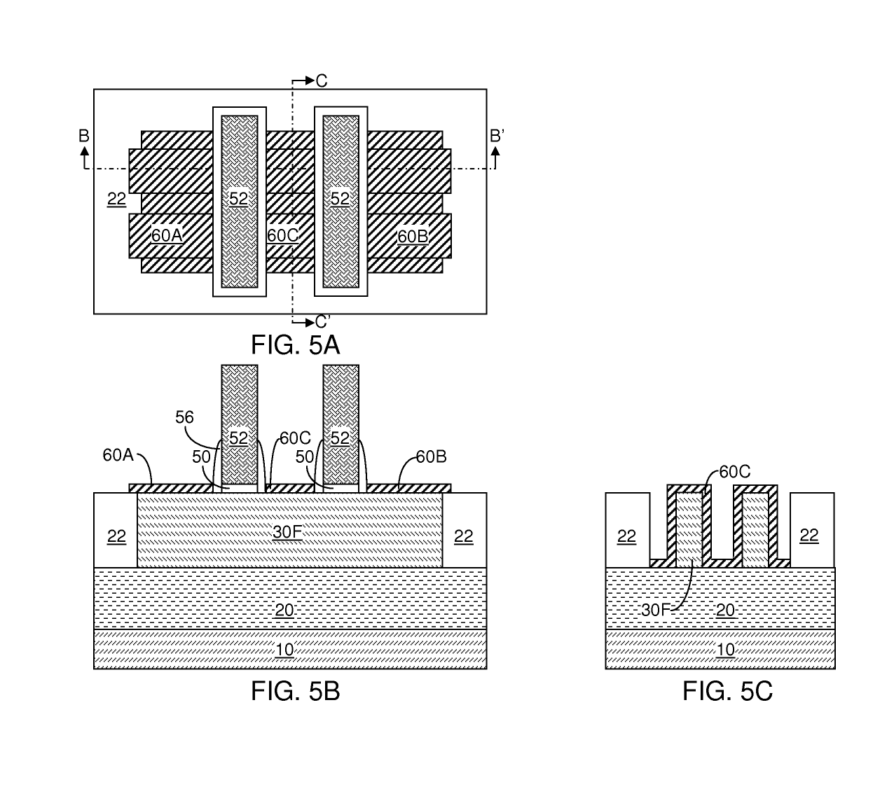

Referring to FIGS. 5A-5C, epitaxially aligned contiguous semiconductor material portions are formed by depositing a semiconductor material, for example, by selective epitaxy. The semiconductor material is selectively deposited on single crystalline surfaces, while not being deposited on non-crystalline surfaces. The selective deposition of the semiconductor material can be performed by concurrently or alternately flowing a reactant gas and an etchant gas into a process chamber into which the first exemplary semiconductor structure is loaded. The deposition on single crystalline surfaces proceeds without any incubation time, while a finite incubation time for nucleation is required on non-crystalline surfaces. By selecting an etch rate that is greater than the net nucleation rate on non-crystalline surfaces and less than the deposition rate on crystalline surfaces, a single crystalline semiconductor material can be deposited only on crystalline surfaces and not on non-crystalline surfaces. The deposited semiconductor material can be, for example, a III-V compound semiconductor material that is lattice matched with, or having a lattice mismatch that allows epitaxial deposition on, the singe crystalline dielectric layer 20 and the semiconductor fins 30F.

The crystalline surfaces include the physically exposed surfaces of the semiconductor fins 30F and the single crystalline dielectric layer 20. The non-crystalline surfaces include surfaces of the shallow trench isolation structure 22, the at least one gate spacer 56, and the at least one gate electrode 52.

Each epitaxially aligned contiguous semiconductor material portion is a contiguous single crystalline semiconductor portion including a single crystalline semiconductor structure in epitaxial alignment with the single crystalline structure of the single crystalline dielectric layer 20. The contiguous single crystalline semiconductor portions can include, for example, a first contiguous single crystalline semiconductor portion 60A deposited at a first end of each semiconductor fin 30F, a second contiguous single crystalline semiconductor portion 60B deposited at a second end of each semiconductor fin 30F, and a third contiguous single crystalline semiconductor portion 60C deposited between a pair of gate stacks (50, 52).

In one embodiment, the contiguous single crystalline semiconductor portions (60A, 60B, 60C) can include a doped semiconductor material that provides an electrical conductive path for conduction of electricity. Each contiguous single crystalline semiconductor portion (60A, 60B, 60C) electrically shorts multiple semiconductor fins 30F. The first contiguous single crystalline semiconductor portion 60A and the second contiguous single crystalline semiconductor portion 60B are formed directly on an end subportion of each of the semiconductor fins 30F, which are semiconductor material portions. As used herein, a “subportion” refers to a part of a larger portion that includes at least another part. The first contiguous single crystalline semiconductor portion 60A and the second contiguous single crystalline semiconductor portion 60B have a single crystalline structure in epitaxial alignment with the single crystalline dielectric layer 20.

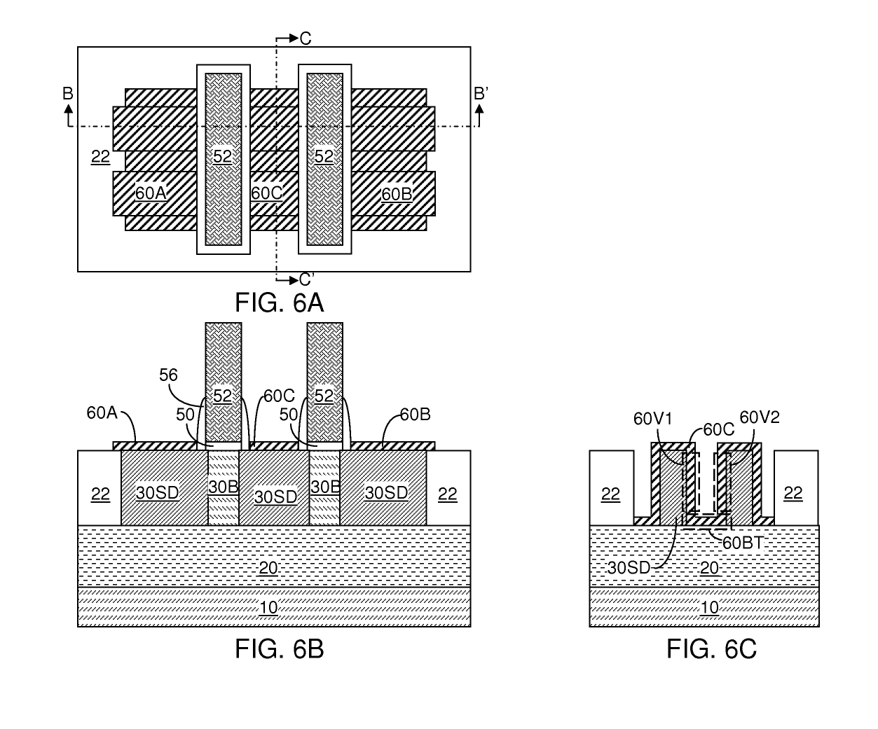

Referring to FIGS. 6A-6C, at least one of an ion implantation process or an anneal process is performed to dope portions of the semiconductor fins 30F that underlie each contiguous single crystalline semiconductor portion (60A, 60B, 60C). The doped portions of the semiconductor fins 30F are converted into source/drain regions 30SD. As used herein, a “source/drain” region can be a source region, a drain region, or a region that can function as a source region or a drain region depending on an operational mode. Each subportion of the semiconductor fins 30F that is not doped by the ion implantation process and/or the anneal process can constitute a body region 30B of a field effect transistor.

In one embodiment, a subportion of each of the plurality of semiconductor fins 30F that underlies a gate electrode 52 can have a doping of the first conductivity type, and end subportions (such as the left-side source/drain region 30SD and the right-side source/drain region 30SD in FIG. 6B) of each of the plurality of semiconductor fins can have a doping of a second conductivity type that is the opposite of the first conductivity type. For example, the first conductivity type can be p-type and the second conductivity type can be n-type, or vice versa.

Each semiconductor fin (30B, 30SD) can be single crystalline, and can be in epitaxial alignment with the single crystalline dielectric layer 20. Each semiconductor fin (30B, 30SD) is a semiconductor material portion. A first semiconductor fin (30B, 30SD), which is a first semiconductor material portion, and a second semiconductor fin (30B, 30SD), which is a second semiconductor material portion, can be laterally spaced from each other along a widthwise direction, which is the horizontal direction within the plane C-C′. A first vertical subportion 60V1 of a contiguous single crystalline semiconductor portion (60A, 60B, or 60C) contacting the first semiconductor fin (30B, 30SD) is laterally spaced from a second vertical subportion 60V2 of the contiguous single crystalline semiconductor portion (60A, 60B, or 60C) contacting the second semiconductor fin (30B, 30SD) and facing the first vertical subportion 60V1.

The single crystalline structure of each contiguous single crystalline semiconductor portion (60A, 60B, 60C) can be in epitaxial alignment with the semiconductor fins (30B, 30SD). A top surface of a bottom subportion 60BT of the contiguous single crystalline semiconductor portion (60A, 60B, 60C) is located below a topmost surface of the plurality of semiconductor fins (30B, 30SD). The shallow trench isolation structure 22 laterally surrounds the plurality of semiconductor fins (30B, 30SD). Vertical surfaces of the plurality of semiconductor fins (30B, 30SD) contact the shallow trench isolation structure 22.

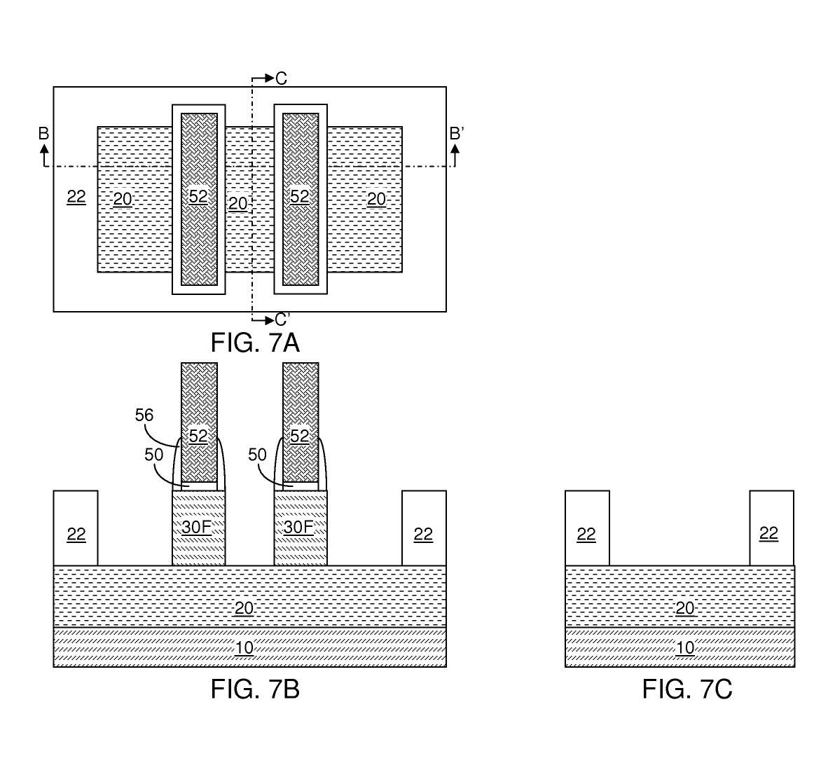

Referring to FIGS. 7A-7C, a second exemplary semiconductor structure according to a second embodiment of the present disclosure is derived from the first exemplary semiconductor structure of FIGS. 4A-4C by removing physically exposed portions of semiconductor fins 30F. The removal of the physically exposed portions of the semiconductor fins 30F can be effected, for example, by an anisotropic etch that is selective to the dielectric material of the shallow trench isolation structure 22, the at least one gate electrode 52, and the at least one gate spacer 56. Thus, physically exposed portions of the plurality of semiconductor fins 30F that are not covered by the at least one gate electrode 52 or the at least one gate spacer 56 are removed by the anisotropic etch. End surfaces of the plurality of semiconductor fins 30F are vertically coincident with outer sidewalls of the at least one gate spacer 56 after the removal of the physically exposed portions of the plurality of semiconductor fins 30F.

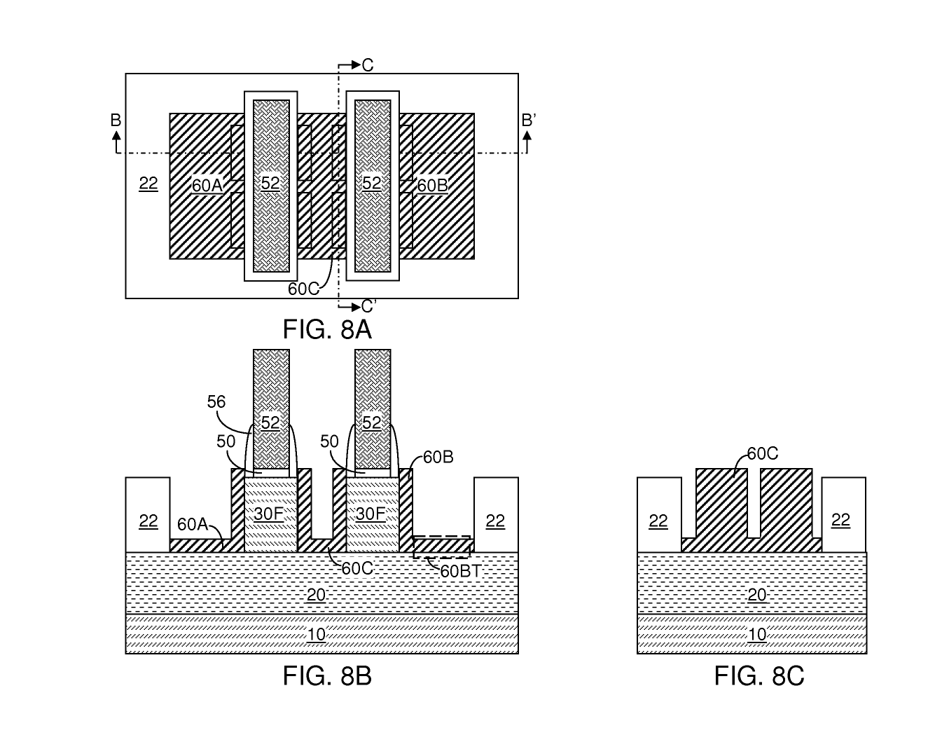

Referring to FIGS. 8A-8C, contiguous single crystalline semiconductor portions are formed directly on an end subportion of each semiconductor fin 30F, which is a semiconductor material portion. The contiguous single crystalline semiconductor portions can include, for example, a first contiguous single crystalline semiconductor portion 60A, a second contiguous single crystalline semiconductor portion 60B, and a third contiguous single crystalline semiconductor portion 60C. The contiguous single crystalline semiconductor portions (60A, 60B, 60C) can be formed by depositing a semiconductor material in epitaxial alignment with the single crystalline dielectric layer 20. The contiguous single crystalline semiconductor portions (60A, 60B, 60C) can be formed by selective epitaxy in the same manner as in the first embodiment. The deposited semiconductor material can be, for example, a III-V compound semiconductor material that is lattice matched with, or having a lattice mismatch that allows epitaxial deposition on, the singe crystalline dielectric layer 20 and the semiconductor fins 30F.

Each of the first, second, and third contiguous single crystalline semiconductor portions (60A, 60B, 60C) contacts an end subportion of each of the plurality of semiconductor fins 30F, and has a single crystalline structure in epitaxial alignment with the single crystalline dielectric layer 20 and the single crystalline structures of the plurality of semiconductor fins 30F. The contiguous single crystalline semiconductor portions (60A, 60B, 60C) are epitaxially aligned contiguous semiconductor material portions that electrically short multiple semiconductor fins 30F. A top surface of a bottom subportion 60BT of each contiguous single crystalline semiconductor portion (60A, 60B, 60C) is located below the topmost surface of the plurality of semiconductor fins 30F.

Each contiguous single crystalline semiconductor portion (60A, 60B, or 60C) is deposited directly on each end surface of the plurality of semiconductor fins 30F that is vertically coincident with outer sidewalls of the at least one gate spacer 56. The first and second contiguous single crystalline semiconductor portion (60A, 60B) can be formed with an L-shaped vertical cross-sectional shape in a vertical cross-sectional view along a vertical plane including the horizontal lengthwise direction (e.g., along the vertical plane B-B′). The shallow trench isolation structure 22 laterally surrounds the plurality of semiconductor fins 30F.

In one embodiment, each contiguous single crystalline semiconductor portion (60A, 60B, or 60C) can be deposited with in-situ doping with dopants of the second conductivity type, or can be implanted with dopants of the second conductivity type. In this case, each semiconductor fin 30F can function as body regions of a field effect transistor, and each contiguous single crystalline semiconductor portion (60A, 60B, 60C) can function as a source/drain region of at least one field effect transistor. Each field effect transistor includes a plurality of semiconductor fins 30F that function as the body of the field effect transistor.

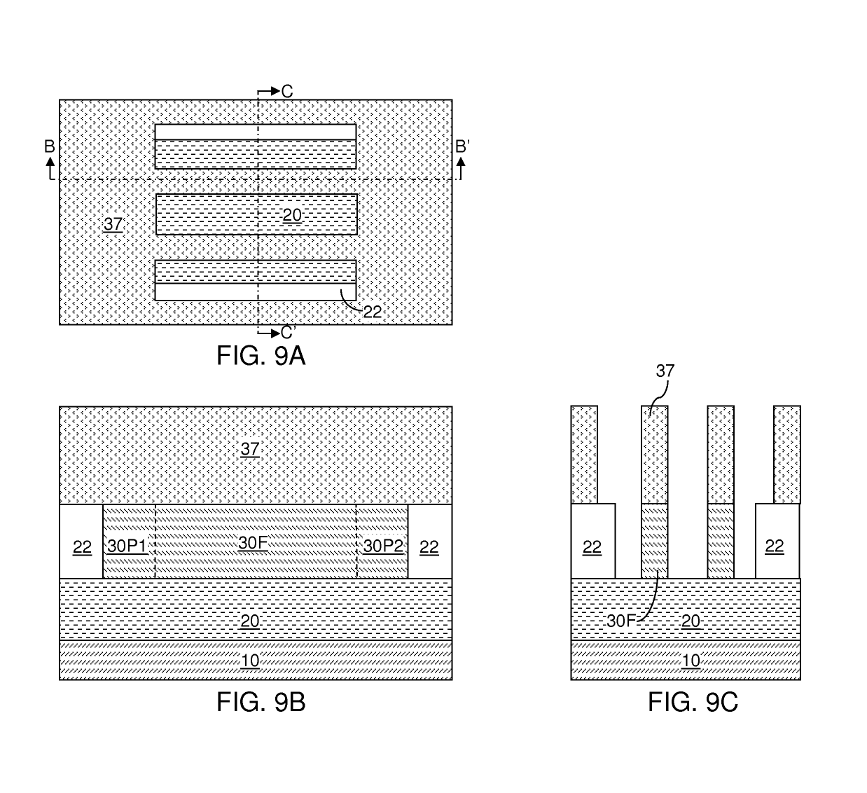

Referring to FIGS. 9A-9C, a third exemplary semiconductor structure according to a third embodiment of the present disclosure can be derived from the first exemplary semiconductor structure of FIGS. 1A-1C. For example, a photoresist layer 37 can be applied over the top semiconductor portion 30 and the shallow trench isolation structure 22. The photoresist layer 37 is lithographically exposed to form a pattern of fins and landing pads over the top semiconductor portion 30. The pattern in the photoresist layer 37 is transferred into the top semiconductor portion 30 by an anisotropic etch that is selective to the dielectric material of the shallow trench isolation structure 22.

The remaining portion of the top semiconductor portion 30 is a semiconductor material portion including a single crystalline semiconductor material in epitaxial alignment with the single crystalline dielectric layer 20. The remaining portion of the top semiconductor portion 30 include a first pad portion 30P1 located at one end, a second pad portion 30P2 located at an opposite end, and a plurality of semiconductor fins 30F connecting the first pad portion 30P1 and the second pad portion 30P2. The first pad portion 30P1, the second pad portion 30P2, and the plurality of semiconductor fins 30F are herein collectively referred to as a semiconductor-fin containing structure (30F, 3OP1, 30P2).

The first semiconductor pad 30P1 and the second semiconductor pad 30P2 are single crystalline, and are in epitaxial alignment with the single crystalline structure of the single crystalline dielectric layer 20. The plurality semiconductor fins 30F laterally contacts the first and second semiconductor pads (30P1, 30P2).

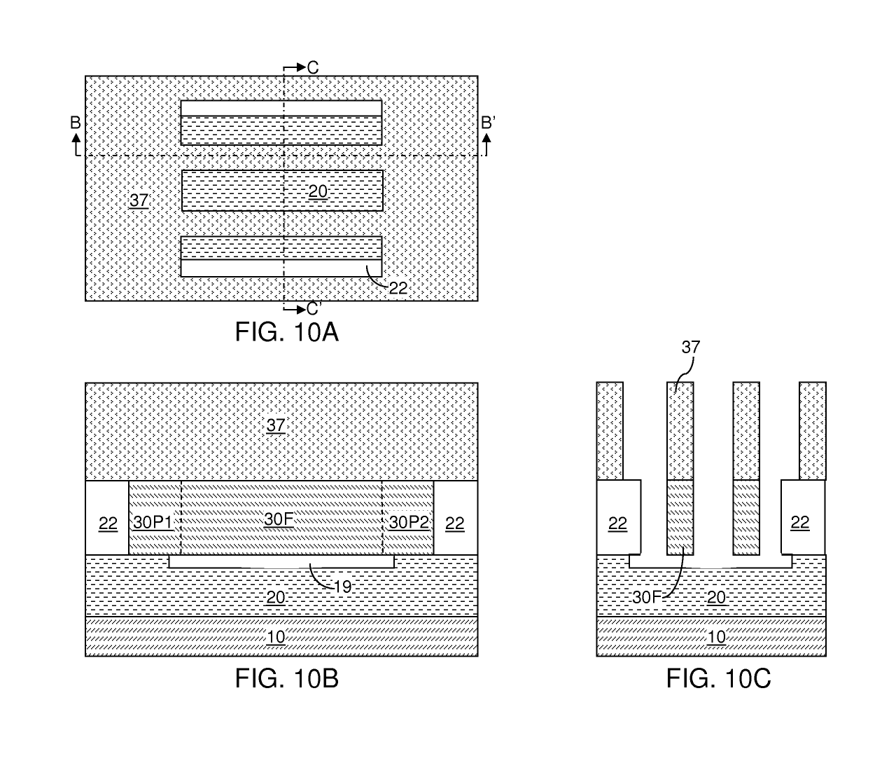

Referring to FIGS. 10A-10C, physically exposed portions of the top surface of the single crystalline dielectric layer 20 are recessed. The first and second semiconductor pads (30P1, 30P2) can be employed as an etch mask during the recessing of the physically exposed portions of the top surface of the single crystalline dielectric layer 20.

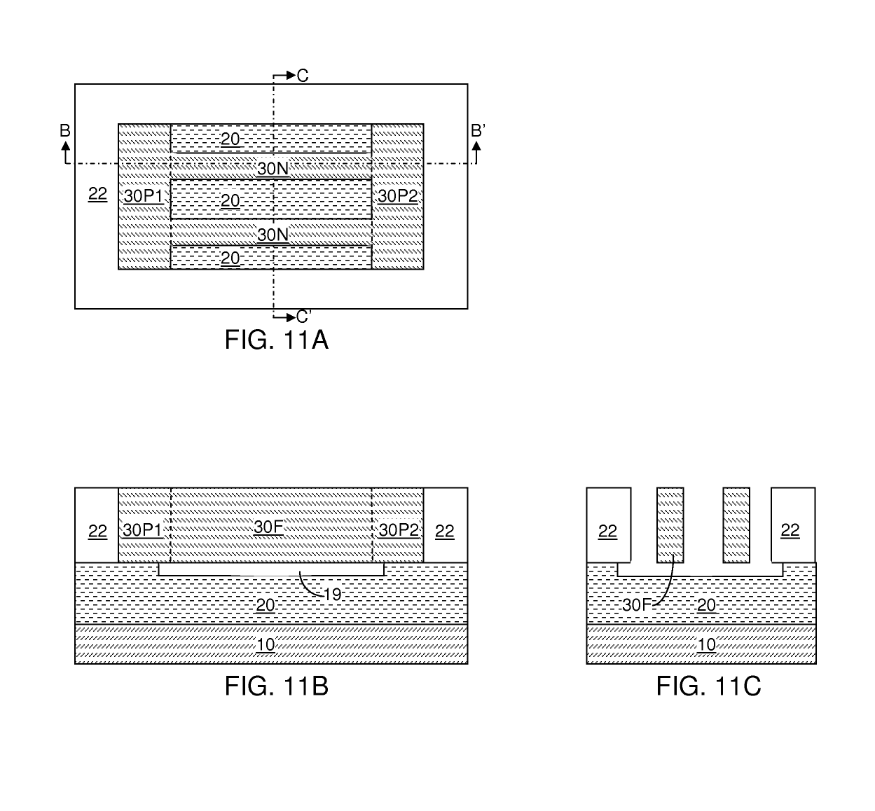

Referring to FIGS. 11A-11C, the photoresist layer 37 is removed selective to the semiconductor-fin containing structure (30F, 3OP1, 30P2) and the shallow trench isolation structure 22, for example, by ashing.

In one embodiment, an isotropic etch can be performed to remove the physically exposed surface portions of the single crystalline dielectric layer 20. The isotropic etch can be a wet etch or a dry etch that removes the dielectric material of the single crystalline dielectric layer 20 selective to the semiconductor material of the semiconductor-fin containing structure (30F, 3OP1, 30P2). Portions of the single crystalline dielectric layer 20 are removed from underneath the plurality of semiconductor fins 30F and from underneath peripheral portions of the first and second pad portions (30P1, 30P2) within an area enclosed by the shallow trench isolation structure 22. The semiconductor fins 30F become suspended above the recessed surface of the single crystalline dielectric layer 20 by the first and second semiconductor pads (30P1, 30P2).

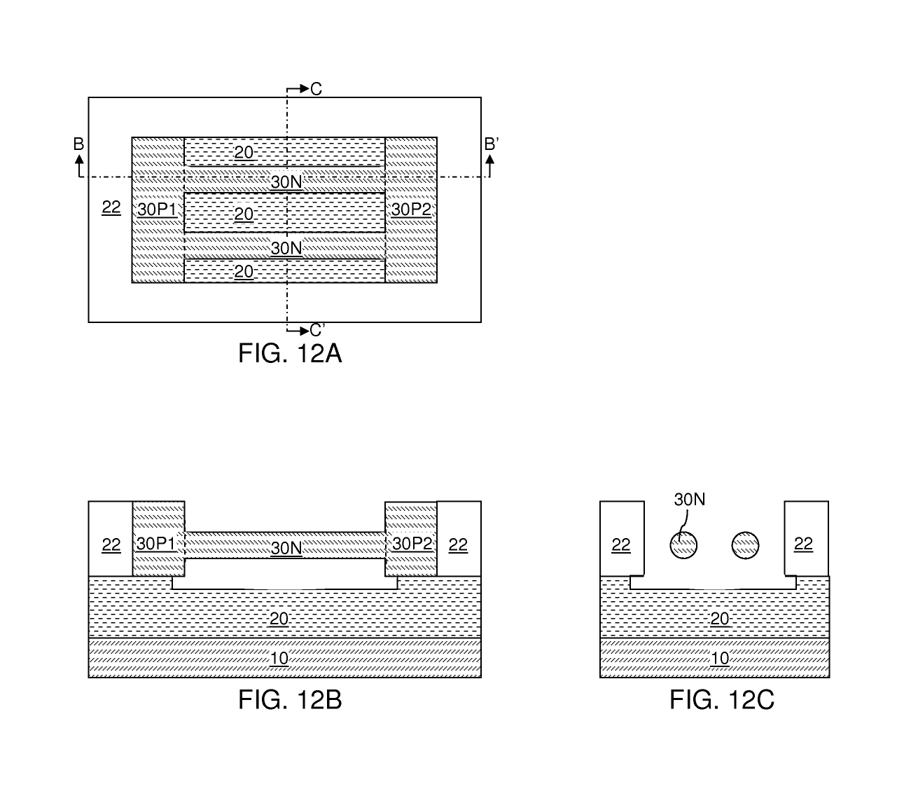

Referring to FIGS. 12A-12C, the plurality of semiconductor fins 30F can be converted into a plurality of semiconductor nanowires 30N by an anneal. For example, the third semiconductor structure can be annealed in a hydrogen-containing environment at an elevated temperature in a range from 850° C. to 1150° C. The plurality of semiconductor fins 30F can be converted into a plurality of semiconductor nanowires 30N. As used herein, a semiconductor nanowire is a semiconductor structure extending along a lengthwise direction with a substantially same cross-sectional shape such that the maximum dimension within the substantially same cross-sectional shape does not exceed 100 nm.

Each semiconductor nanowire 30N can have a non-rectangular vertical cross-sectional shape along planes perpendicular to the lengthwise direction of the plurality of semiconductor nanowires 30 after the anneal. For example, the plurality of semiconductor nanowires 30N can have a circular or elliptical vertical cross-sectional shape as illustrated in FIG. 12C. Each first end of the semiconductor nanowire 30N is attached to the first semiconductor pad 30P1, and each second end of the semiconductor nanowire 30N is attached to the second semiconductor pad 30P2. The semiconductor-fin containing structure (30F, 30P1, 30P2) is converted into a semiconductor-nanowire containing structure (30P, 30P1, 30P2).

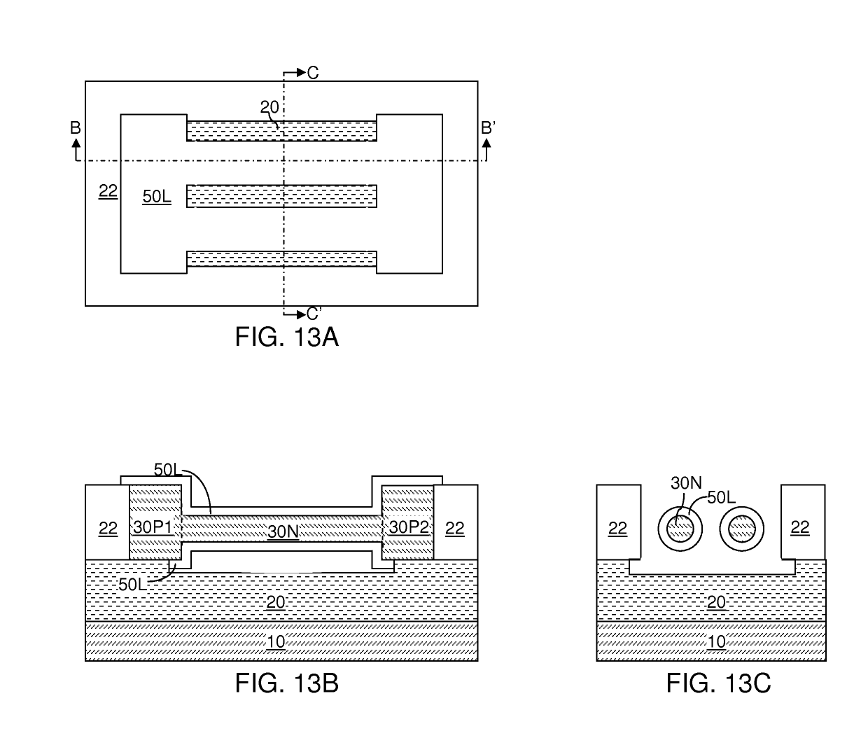

Referring to FIGS. 13A-13C, a gate dielectric layer 50L can be formed at least on physically exposed surfaces of the semiconductor-nanowire containing structure (30N, 30P1, 30P2). Additionally, the gate dielectric layer 50L may be formed on physically exposed surfaces of the shallow trench isolation structure 22 and/or physically exposed surfaces of the single crystalline dielectric layer 20. The gate dielectric layer 50L can include a high dielectric constant (high-k) dielectric material having a dielectric constant greater than 7.9 and/or a conventional gate dielectric material such as silicon oxide, silicon nitride, and/or silicon oxynitride. The gate dielectric layer 50L can be formed by conversion of surface portions of the semiconductor material in the semiconductor-nanowire containing structure (30N, 30P1, 30P2) into a dielectric material such as a dielectric oxide, a dielectric nitride, and/or a dielectric oxynitride. Alternately or additionally, the gate dielectric layer 50L can be formed by conformal deposition of a dielectric material such as a metallic oxide, a metallic nitride, and/or a metallic oxynitride. The conversion of surface portions of the semiconductor material into a dielectric material can be performed, for example, by thermal oxidation, thermal nitridation, plasma oxidation, and/or plasma nitridation. The deposition of a dielectric material can be performed, for example, by atomic layer deposition (ALD) or chemical vapor deposition (CVD).

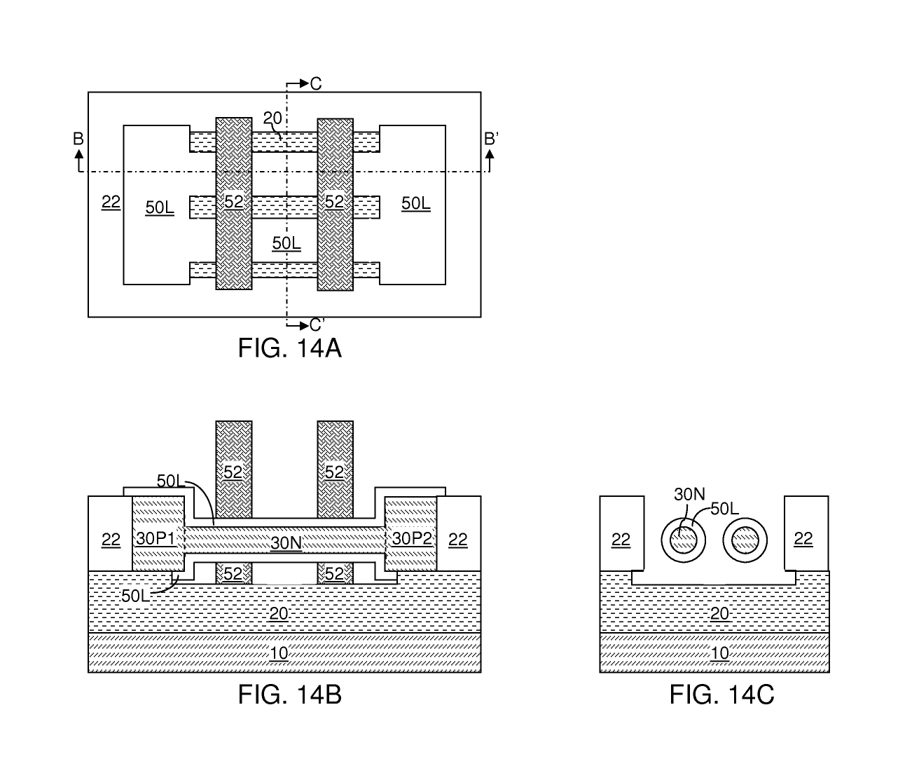

Referring to FIGS. 14A-14C, at least one gate electrode 52 can be formed over the plurality of semiconductor nanowires 30N. Each gate electrode 52 straddles a portion of each semiconductor nanowires 30N. Each gate electrode 52 includes at least one conductive material, which can be a metallic material and/or a doped semiconductor material. The at least one gate electrode 52 can be formed by depositing at least one conductive material layer, and patterning the conductive material layer, for example, employing lithographic patterning of a photoresist layer (not shown) and transfer of the pattern in the photoresist layer into the conductive material layer by an anisotropic etch. The photoresist layer can be subsequently removed. Optionally, the gate dielectric layer 50L can be employed as an etch stop layer during the anisotropic etch. Each gate electrode wraps around a plurality of semiconductor nanowires 30N, and includes portions that underlie the semiconductor nanowires 30N.

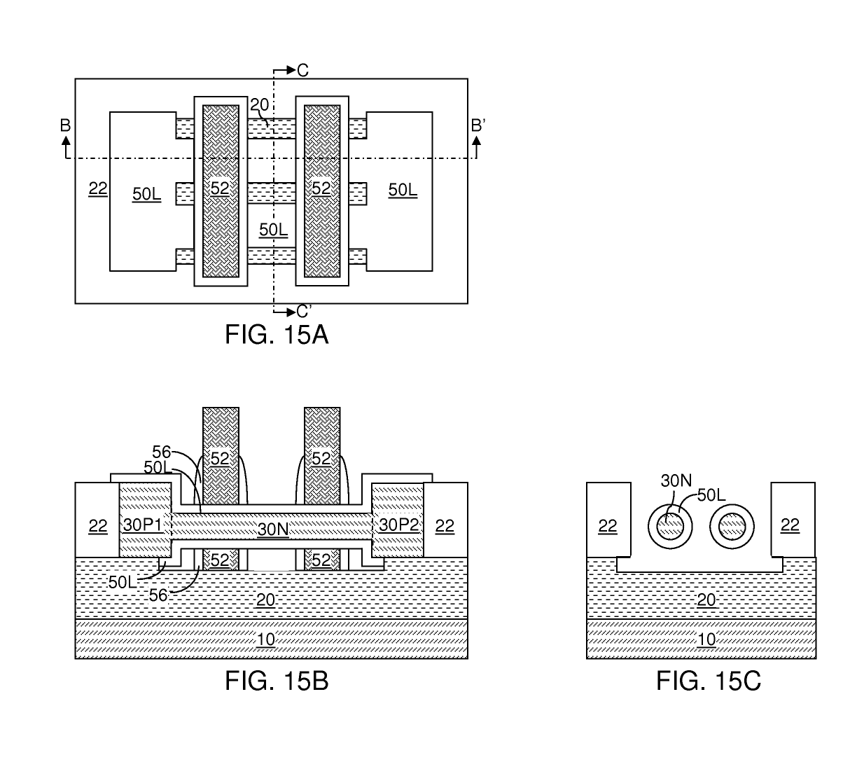

Referring to FIGS. 15A-15C, a gate spacer 56 can be formed around each gate stack (50, 52), for example, by depositing a dielectric material layer and anisotropically etching the dielectric material layer. Each remaining vertical portions of the dielectric material layer constitutes a gate spacer 56. Each gate spacer 56 laterally surrounds a gate electrode 52.

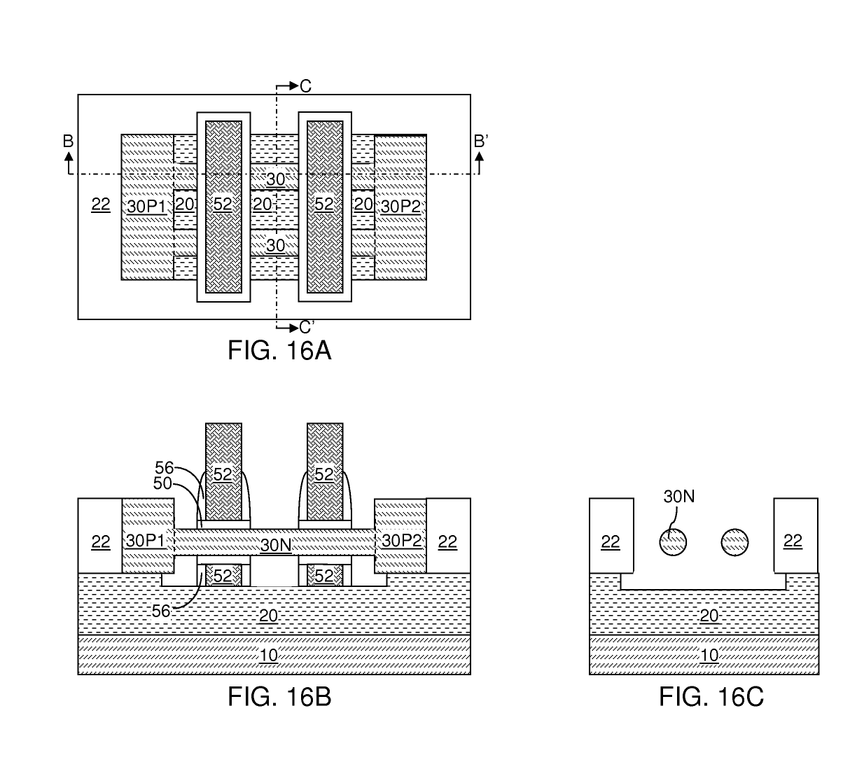

Referring to FIGS. 16A-16C, physically exposed portions of the gate dielectric layer 50L are removed selective to the semiconductor-nanowire containing structure (30N, 30P1, 30P2), for example, by an etch. The etch can be a wet etch or a dry etch. Each remaining portion of the gate dielectric layer 50L is a gate dielectric 50 that laterally surrounds a semiconductor nanowire 30N. Each gate electrode 52 wraps around each of the plurality of semiconductor nanowires 30N.

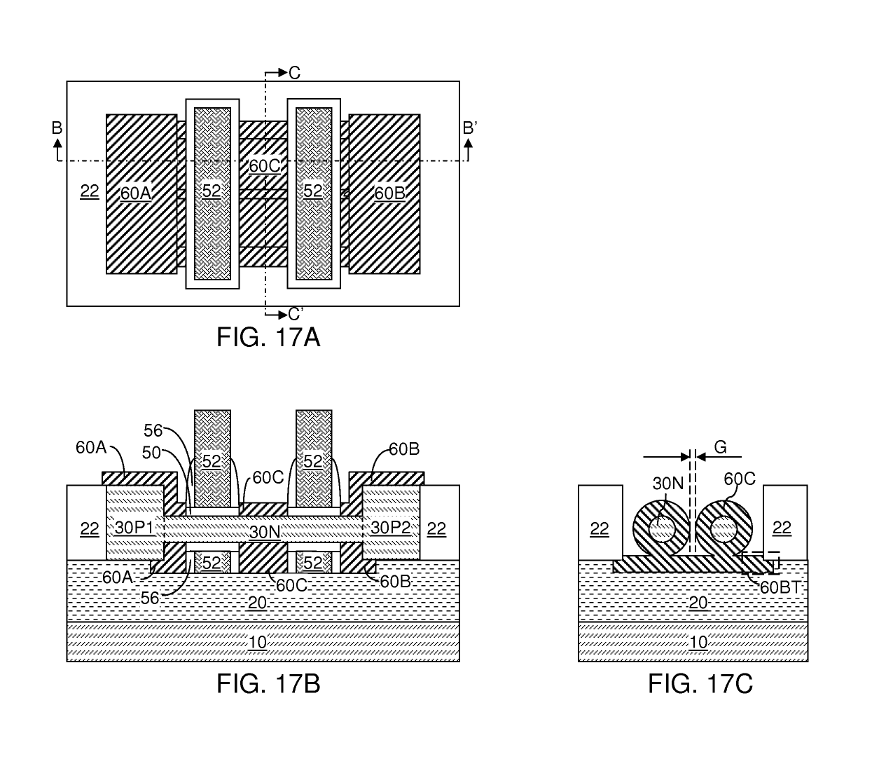

Referring to FIGS. 17A-17C, epitaxially aligned contiguous semiconductor material portions are formed by depositing a semiconductor material, for example, by selective epitaxy. The semiconductor material is selectively deposited on single crystalline surfaces, while not being deposited on non-crystalline surfaces. The selective deposition of the semiconductor material can be performed by concurrently or alternately flowing a reactant gas and an etchant gas into a process chamber into which the third exemplary semiconductor structure is loaded. The deposition on single crystalline surfaces proceeds without any incubation time, while a finite incubation time for nucleation is required on non-crystalline surfaces. By selecting an etch rate that is greater than the net nucleation rate on non-crystalline surfaces and less than the deposition rate on crystalline surfaces, a single crystalline semiconductor material can be deposited only on crystalline surfaces and not on non-crystalline surfaces. The deposited semiconductor material can be, for example, a III-V compound semiconductor material that is lattice matched with, or having a lattice mismatch that allows epitaxial deposition on, the singe crystalline dielectric layer 20 and the semiconductor nanowires 30N.

The crystalline surfaces include the physically exposed surfaces of the semiconductor nanowires 30N and the single crystalline dielectric layer 20. The non-crystalline surfaces include surfaces of the shallow trench isolation structure 22, the at least one gate spacer 56, and the at least one gate electrode 52.

Each epitaxially aligned contiguous semiconductor material portion is a contiguous single crystalline semiconductor portion including a single crystalline semiconductor structure in epitaxial alignment with the single crystalline structure of the single crystalline dielectric layer 20. The contiguous single crystalline semiconductor portions can include, for example, a first contiguous single crystalline semiconductor portion 60A deposited at a first end of each semiconductor nanowire 30N, a second contiguous single crystalline semiconductor portion 60B deposited at a second end of each semiconductor nanowire 30N, and a third contiguous single crystalline semiconductor portion 60C deposited between a pair of gate stacks (50, 52).

In one embodiment, the contiguous single crystalline semiconductor portions (60A, 60B, 60C) can include a doped semiconductor material that provides an electrical conductive path for conduction of electricity. Each contiguous single crystalline semiconductor portion (60A, 60B, 60C) electrically shorts multiple semiconductor nanowires 30N. The first contiguous single crystalline semiconductor portion 60A and the second contiguous single crystalline semiconductor portion 60B are formed directly on an end subportion of each of the semiconductor nanowires 30N, which are semiconductor material portions. The first contiguous single crystalline semiconductor portion 60A and the second contiguous single crystalline semiconductor portion 60B have a single crystalline structure in epitaxial alignment with the single crystalline dielectric layer 20.

Each semiconductor nanowire 30N is a semiconductor material portion. In one embodiment, a first subportion of the third contiguous single crystalline semiconductor portion 60C contacting a first semiconductor nanowire 30N can be laterally spaced from a second subportion of the third contiguous single crystalline semiconductor portion 60C contacting the second semiconductor nanowire 30N. Each semiconductor nanowire 30N can be single crystalline, and the single crystalline structure of each contiguous single crystalline semiconductor portion (60A, 60B, 60C) can be in epitaxial alignment with the semiconductor nanowires 30N.

A horizontal interface between each contiguous single crystalline semiconductor portion (60A, 60B, 60C) and the single crystalline dielectric layer 20 is vertically recessed relative to a horizontal interface between the single crystalline dielectric layer 20 and the first and second semiconductor pads (30P1, 30P2).

The plurality of semiconductor nanowires 30N extends along a horizontal lengthwise direction, and has a uniform vertical cross-sectional shape along the horizontal lengthwise direction. The uniform vertical cross-sectional shape can have a curved periphery. For example, the uniform vertical cross-sectional shape can be a circular shape or an elliptical shape. A bottommost surface of the plurality of semiconductor nanowires 30N can be located above the topmost surface of the single crystalline dielectric layer 20.

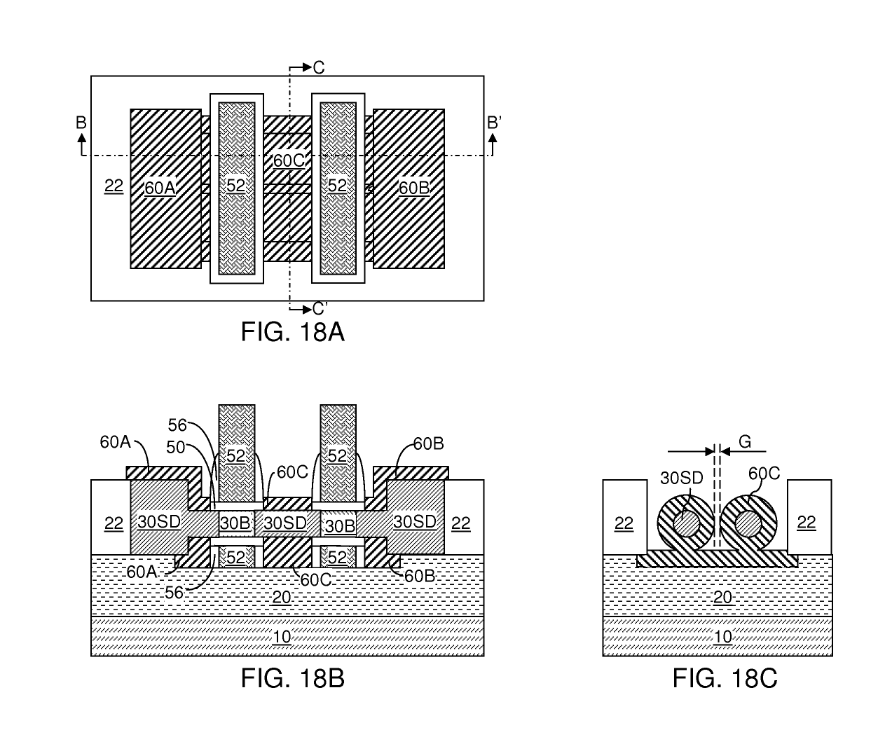

Referring to FIGS. 18A-18C, at least one of an ion implantation process or an anneal process is performed to dope portions of the semiconductor-nanowire containing structure (30N, 30P1, 30P2) that underlie each contiguous single crystalline semiconductor portion (60A, 60B, 60C). The portions of the semiconductor-nanowire containing structure (30N, 30P1, 30P2) doped by the ion implantation process or by the anneal process are converted into source/drain regions 30SD. Each subportion of the semiconductor nanowires 30N that is not doped by the ion implantation process and/or the anneal process can constitute a body region 30B of a field effect transistor.

In one embodiment, each subportion of the semiconductor-nanowire containing structure (30SD, 30B) that underlies a gate electrode 52 can be a body region 30B having a doping of the first conductivity type. End subportions (such as the left-side source/drain region 30SD and the right-side source/drain region 30SD in FIG. 6B) of the semiconductor-nanowire containing structure (30SD, 30B) can have a doping of a second conductivity type that is the opposite of the first conductivity type. For example, the first conductivity type can be p-type and the second conductivity type can be n-type, or vice versa.

Each of the semiconductor-nanowire containing structures (30SD, 30B) can be composed of a single crystalline semiconductor material, and can be in epitaxial alignment with the single crystalline dielectric layer 20. Each semiconductor nanowire is a semiconductor material portion. A first semiconductor nanowire, which is a first semiconductor material portion, and a second semiconductor nanowire, which is a second semiconductor material portion, can be laterally spaced from each other along a widthwise direction, which is the horizontal direction within the plane C-C′. A first subportion of a contiguous single crystalline semiconductor portion (60A, 60B, or 60C) contacting the first semiconductor nanowire is laterally spaced from a second subportion of the contiguous single crystalline semiconductor portion (60A, 60B, or 60C) contacting the second semiconductor nanowire by a lateral gap G. The lateral gap G is the minimum dimension between the first subportion and the second subportion.

The single crystalline structure of each contiguous single crystalline semiconductor portion (60A, 60B, 60C) can be in epitaxial alignment with the semiconductor-nanowire containing structure (30SD, 30B). A top surface of a bottom subportion 60BT of the contiguous single crystalline semiconductor portion (60A, 60B, 60C) is located below a topmost surface of the plurality of semiconductor nanowires. The shallow trench isolation structure 22 laterally surrounds the plurality of semiconductor nanowires. Vertical surfaces of the semiconductor-nanowire containing structure (30SD, 30B) contact the shallow trench isolation structure 22.

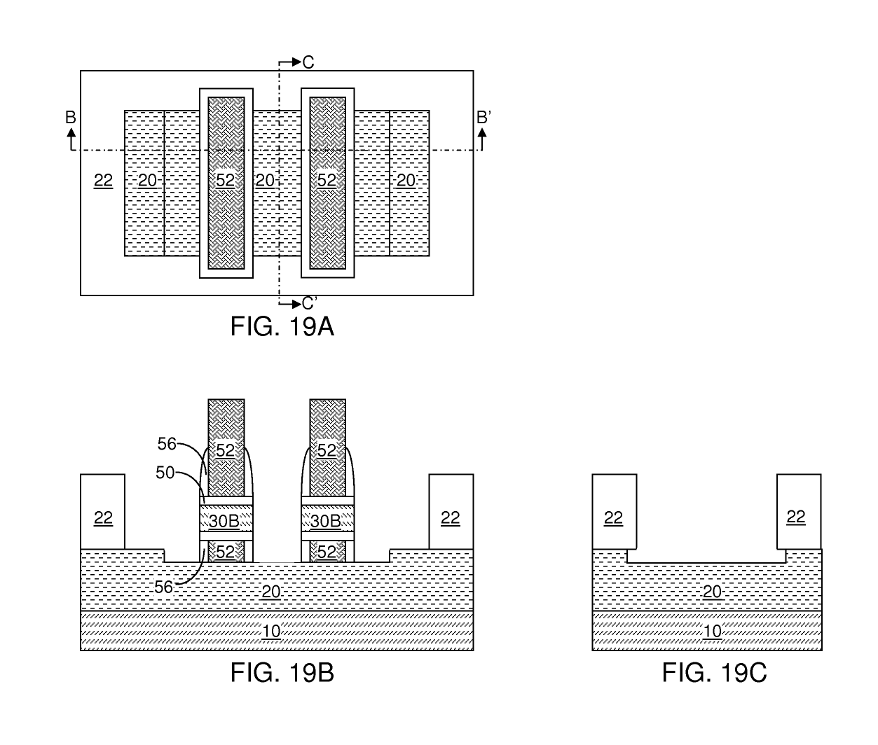

Referring to FIGS. 19A-19C, a fourth exemplary semiconductor structure according to a fourth embodiment of the present disclosure is derived from the third exemplary semiconductor structure of FIGS. 16A-16C by removing physically exposed portions of the semiconductor-nanowire containing structure (30N, 30P1, 30P2). The removal of the physically exposed portions of the semiconductor-nanowire containing structure (30N, 30P1, 30P2) can be effected, for example, by an anisotropic etch that is selective to the dielectric material of the shallow trench isolation structure 22, the at least one gate electrode 52, and the at least one gate spacer 56. Thus, physically exposed portions of the semiconductor-nanowire containing structure (30N, 3OP1, 30P2) that are not covered by the at least one gate electrode 52 or the at least one gate spacer 56 are removed by the anisotropic etch. The remaining portions of the semiconductor-nanowire containing structure (30N, 30P1, 30P2) constitute a plurality of physically disjoined semiconductor material portions, which are herein referred to as body regions 30B. End surfaces of the body regions 30B are vertically coincident with outer sidewalls of the at least one gate spacer 56 after the removal of the physically exposed portions of the semiconductor-nanowire containing structure (30N, 30P1, 30P2).

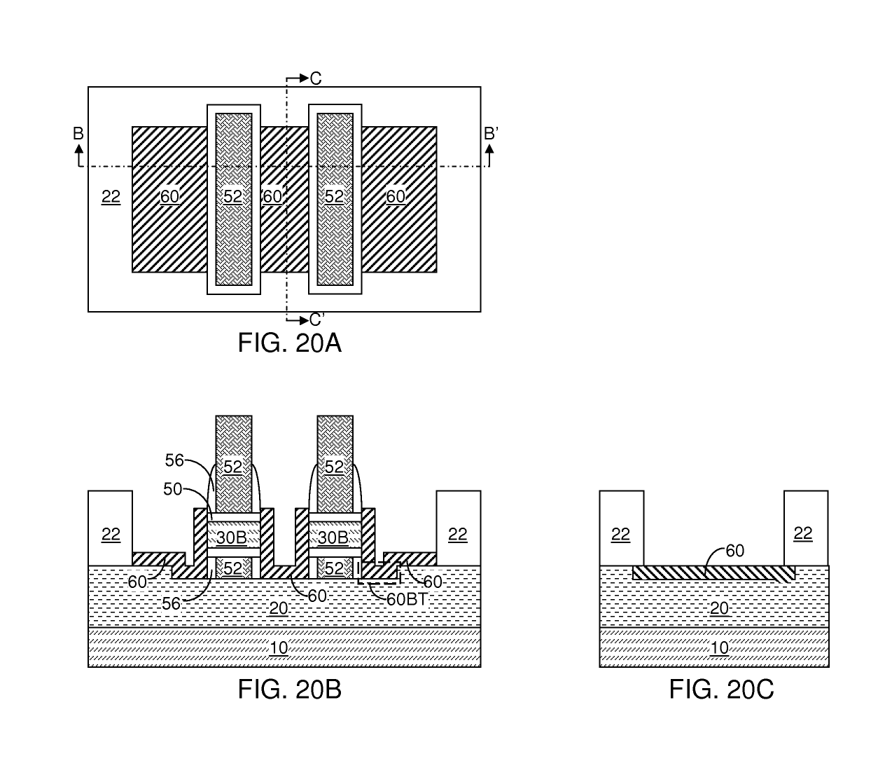

Referring to FIGS. 20A-20C, contiguous single crystalline semiconductor portions are formed directly on an end subportion of each body regions 30B, which is a semiconductor material portion. The contiguous single crystalline semiconductor portions can include, for example, a first contiguous single crystalline semiconductor portion 60A, a second contiguous single crystalline semiconductor portion 60B, and a third contiguous single crystalline semiconductor portion 60C. The contiguous single crystalline semiconductor portions (60A, 60B, 60C) can be formed by depositing a semiconductor material in epitaxial alignment with the single crystalline dielectric layer 20. The contiguous single crystalline semiconductor portions (60A, 60B, 60C) can be formed by selective epitaxy in the same manner as in the third embodiment. The deposited semiconductor material can be, for example, a III-V compound semiconductor material that is lattice matched with, or having a lattice mismatch that allows epitaxial deposition on, the singe crystalline dielectric layer 20 and the body regions.

Each of the first, second, and third contiguous single crystalline semiconductor portions (60A, 60B, 60C) contacts an end subportion of a plurality of body regions 30B, and has a single crystalline structure in epitaxial alignment with the single crystalline dielectric layer 20 and the single crystalline structures of the body regions 30B. The contiguous single crystalline semiconductor portions (60A, 60B, 60C) are epitaxially aligned contiguous semiconductor material portions that electrically short multiple body regions 30B. A top surface of a bottom subportion 60BT of each contiguous single crystalline semiconductor portion (60A, 60B, 60C) is located below the topmost surface of the plurality of body regions 30B.

Each contiguous single crystalline semiconductor portion (60A, 60B, or 60C) is deposited directly on end surfaces of a plurality of body regions 30B that are vertically coincident with outer sidewalls of the at least one gate spacer 56. The shallow trench isolation structure 22 laterally surrounds the plurality of body regions 30B.

In one embodiment, each contiguous single crystalline semiconductor portion (60A, 60B, or 60C) can be deposited with in-situ doping with dopants of the second conductivity type, or can be implanted with dopants of the second conductivity type. A plurality of body regions 30B contacted by a same pair of contiguous single crystalline semiconductor portion (60A, 60B, 60C) constitute a body of a field effect transistor. Each of the contiguous single crystalline semiconductor portions (60A, 60B, 60C) can function as a source/drain region of at least one field effect transistor.

In various embodiments of the present disclosure, a recessed top surface of the single crystalline dielectric layer 20 provides a single crystalline surface on which a single crystalline semiconductor material can be deposited with epitaxial alignment. Further, single crystalline surfaces of at least one semiconductor material portion function as additional single crystalline surface on which the single crystalline semiconductor material can be deposited with epitaxial alignment. Thus, the deposited single crystalline semiconductor material is in epitaxial alignment with the single crystalline dielectric layer 20 and the at least one semiconductor material portion. The deposited single crystalline semiconductor material can be deposited with in-situ doping, or can be subsequently doped by ion implantation, to form a doped semiconductor material portions, which can be source/drain regions of at least one field effect transistor.

While the disclosure has been described in terms of specific embodiments, it is evident in view of the foregoing description that numerous alternatives, modifications and variations will be apparent to those skilled in the art. Each of the embodiments described herein can be implemented individually or in combination with any other embodiment unless expressly stated otherwise or clearly incompatible. Accordingly, the disclosure is intended to encompass all such alternatives, modifications and variations which fall within the scope and spirit of the disclosure and the following claims.

What is claimed is:

1. A method of forming a semiconductor structure comprising:
forming at least one semiconductor material portion on a single crystalline dielectric layer;
forming a gate electrode straddling said at least one semiconductor material portion; and
forming a contiguous single crystalline semiconductor portion directly on an end subportion of each of said at least one semiconductor material portion by depositing a semiconductor material in epitaxial alignment with said single crystalline dielectric layer.

2. The method of claim 1, wherein said at least one semiconductor material portion has a doping of a first conductivity type, and said method further comprises doping said end subportion of each of said at least one semiconductor material portion with dopants of a second conductivity type that is the opposite of said first conductivity type.

3. The method of claim 1, further comprising recessing a portion of a top surface of said single crystalline dielectric layer, wherein said contiguous single crystalline semiconductor portion is formed directly on said recessed portion of said top surface of said single crystalline dielectric layer.

4. The method of claim 1, wherein said at least one semiconductor material portion is a plurality of semiconductor fins having parallel vertical sidewalls.

5. The method of claim 4, wherein each of said plurality of semiconductor fins is single crystalline and is in epitaxial alignment with said single crystalline dielectric layer.

6. The method of claim 5, further comprising forming a shallow trench isolation structure on said single crystalline dielectric layer, wherein vertical surfaces of said at least one semiconductor material portion contact said shallow trench isolation structure.

7. The method of claim 6, wherein each of said at least one semiconductor material portion extends along a horizontal lengthwise direction, has a substantially rectangular vertical cross-sectional shape within vertical planes perpendicular to said horizontal lengthwise direction.

8. The method of claim 6, further comprising:
forming a gate spacer laterally around said gate electrode; and
removing physically exposed portions of said at least one semiconductor portion that are not covered by said gate electrode or said gate spacer, wherein end surfaces of said at least one semiconductor portion are vertically coincident with outer sidewalls of said gate spacer after said removal of said physically exposed portions.

9. The method of claim 1, wherein said at least one semiconductor material portion is a plurality of semiconductor nanowires.

10. The method of claim 9, further comprising forming a first semiconductor pad and a second semiconductor pad over said single crystalline dielectric layer, wherein each first end of said semiconductor nanowire is attached to said first semiconductor pad, and each second end of said semiconductor nanowire is attached to said second semiconductor pad.

11. The method of claim 9, further comprising
forming a plurality semiconductor fins laterally contacting said first and second semiconductor pads;
removing portions of said single crystalline dielectric layer from underneath said plurality of semiconductor fins; and
converting said plurality of semiconductor fins into a plurality of semiconductor nanowires by an anneal.

12. The method of claim 9, wherein said gate electrode wraps around each of said plurality of semiconductor nanowires.

13. The method of claim 9, wherein said plurality of semiconductor nanowires extends along a horizontal lengthwise direction, and has a uniform vertical cross-sectional shape along said horizontal lengthwise direction.

14. A semiconductor structure comprising:
a substrate including a single crystalline dielectric layer;
at least one semiconductor material portion located on said single crystalline dielectric layer;
a gate electrode straddling said at least one semiconductor material portion; and
a contiguous single crystalline semiconductor portion contacting an end subportion of each of said at least one semiconductor material portion and having a single crystalline structure in epitaxial alignment with said single crystalline dielectric layer.

15. The semiconductor structure of claim 14, wherein a subportion of each of said at least one semiconductor material portion underlying said gate electrode has a doping of a first conductivity type, and said end subportion of each of said at least one semiconductor material portion has a doping of a second conductivity type that is the opposite of said first conductivity type.

16. The semiconductor structure of claim 14, wherein each of said at least one semiconductor material portion is single crystalline, and is in epitaxial alignment with said single crystalline dielectric layer.

17. The semiconductor structure of claim 14, wherein said at least one semiconductor material portion is a plurality of semiconductor material portions.

18. The semiconductor structure of claim 14, wherein a top surface of a bottom subportion of said contiguous single crystalline semiconductor portion is located below a topmost surface of said at least one semiconductor material portion.

19. The semiconductor structure of claim 14, further comprising a shallow trench isolation structure located above said single crystalline dielectric layer and laterally surrounding said at least one semiconductor material portion.

20. The semiconductor structure of claim 14, wherein said at least one semiconductor material portion is a plurality of semiconductor fins having parallel vertical sidewalls.

21. The semiconductor structure of claim 20, wherein each of said plurality of semiconductor fins is single crystalline and is in epitaxial alignment with said single crystalline dielectric layer.

22. The semiconductor structure of claim 14, wherein said at least one semiconductor material portion is a plurality of semiconductor nanowires.

23. The semiconductor structure of claim 22, wherein each first end of said semiconductor nanowire is attached to a first semiconductor pad, and each second end of said semiconductor nanowire is attached to a second semiconductor pad.

24. The semiconductor structure of claim 23, wherein a bottommost surface of said plurality of semiconductor nanowires is located above a topmost surface of said single crystalline dielectric layer.

25. The semiconductor structure of claim 23, wherein said plurality of semiconductor nanowires extends along a horizontal lengthwise direction, and has a uniform vertical cross-sectional shape along said horizontal lengthwise direction.
